(19) United States
(12) Patent Application Publication
(10) Pub. No.: US 2016/0359426 A1
(43) Pub. Date: Dec. 8, 2016

(54) PACKAGING METHOD FOR VERY HIGH DENSITY CONVERTERS

(71) Applicant: ROMPOWER ENERGY SYSTEMS INC., Tucson, AZ (US)

(72) Inventors: Ionel Jitaru, Tucson, AZ (US); Ian Poynton, Marana, AZ (US); Enrique Velasco, Marana, AZ (US)

(73) Assignee: Rompower Energy Systems, Inc., Tucson, AZ (US)

(21) Appl. No.: 15/103,617

(22) PCT Filed: Dec. 11, 2014
(86) PCT No.: PCT/US14/69733

§ 371 Date: Jun. 10, 2016

Related U.S. Application Data
(60) Provisional application No. 61/914,664, filed on Dec. 11, 2013.

(51) Int. Cl. H02M 7/00; H02M 7/21; H05K 1/14; H05K 1/02; H05K 9/00; H05K 1/18

(52) U.S. Cl. CPC H02M 7/003; H05K 9/0071; H05K 1/181; H05K 1/14; H05K 1/0203; H02M 7/21; H05K 2201/042; H05K 2201/062; H05K 2201/10166; H05K 2201/10015

(57) ABSTRACT

Meeting todays requirement in power supply technology demands significant technological advancement in optimizing circuit topology, components and materials, thermal and packaging designs. These requirements are being pushed mainly by continuously increasing power density and efficiency requirements. Ultimately, these trends will come to a point whereby limitations from the above mentioned technological advancements is dependent on one of the above, which is the packaging design. To realize this dependence, we need to look at the growing power systems for modern equipment out there. Let us enumerate some of the available AC adapters in terms of power densities of a 45 W adapter. Firstly, square type architecture introduced by Apple is about 7 W/in3, considering the packaging has a profile limitation whereby its AC plug is removable thus occupying relatively bigger chunk of the volume. The next one is by Asus of similar profile to Apple incorporating the AC Plug eliminating the socket assembly in the packaging; which packs about 9 W/in3. Lastly, the typical rectangular profile by Eos which is about 7 W/in3. As for this particular embodiment it is about 40% smaller in profile, in contrast to the 45 W Apple packaging, with increase power density of about 12 W/in3. Packaging design method plays a great role in achieving the above requirements for a very high density converters.

### RELATED APPLICATION/CLAIM OF PRIORITY

This Application is related to and claims priority from U.S. provisional application Ser. No. 61/914,664, filed Dec. 11, 2013, which application is incorporated by reference herein.

### FIELD OF THE INVENTION

The present invention relates generally to converters particularly the AC to DC power adapter. A converter having strategically improved packaging in heightening the power density by tackling the overall construction of the housing and reducing its size.

### BACKGROUND OF THE INVENTION

With the advent technological advancement in portable computing and mobile devices, the trends in designing the above devices are leaning towards portability and miniaturization. In accordance to the above advancements, the converter particularly the AC to DC power adapter correspondingly driven to the same development as well as pushing the power density and efficiency to its limits.

The present disclosure relates to converters and, particularly, AC to DC adapter for conveniently providing power to these portable computing and mobile devices. There are several products in the market today and they vary mainly in physical sizes mainly defined by the power they are designed for. The odd part is that some of these devices are thin and lightweight in profile and yet the converter it demands is bulky and heavy.

The demand dictates the present invention to improve the techniques for charging or providing power to the above devices. To realize this feat to make the invention small portable and efficient; constraints such as devices and materials, topology employed, system architectures, and packaging design, need to be enumerated and tackle accordingly.

### BRIEF SUMMARY OF THE INVENTION

The main objective of the present invention is to provide a high power density converter for most portable computing and mobile devices that is smaller and efficient than any of the converters out there. Packaging design method is the main emphasis of this invention.

The present invention's purpose and advantages will become apparent from the following descriptions below. As shown in FIG. 2, A converter (1) consisting of strategically arranged three boards, such that the power board (2), primary board (3), and secondary board (4), when assembled together fits in an optimal sized chassis accordingly achieving very high power density converter. The converter's (1) plastic chassis consists of top cover (6) and bottom cover (7). The bottom cover (7) contains extrusions to satisfy the safety requirements for this type of converter. Safety requirements is further supported by an additional insulation piece (8) which is placed purposely within the confines of the power board (2) to meet the creepage and clearance path requirement for such converter. The power board (2) contains the most heat dissipating devices such as transformer (11), secondary MOSFETS (12) and output capacitors. As for the primary board (3) it contains the bulk capacitor (20), primary MOSFETS, primary control, input bridge rectifier (21), and EMI filter circuitry. As for the secondary board (4) it contains mainly the secondary controller, output switch, and output electrolytic capacitor (19). In order to distribute the thermal concerns produced mainly by the power board (2), it is arranged such that it is placed laterally along the top side of both the top (6) and bottom (7) covers of the converter (1). The arrangement of the three boards will require an interconnection between the primary board (3) and the secondary board (4) and this is done by introducing and a signal board (9) which may contain additional circuitry or plain traces necessary to communicate with the two boards, Primary (3) and secondary (4) boards. This signal board (9) maybe use as mechanical fixture or support for both boards (primary (3) and secondary (4) boards). An additional support called bridge reflector (10) for both boards {primary (3) and secondary (4) boards} are introduced and fastened at the back of the input bridge (21) to redirect the heat generated by the input bridge (21).

### BRIEF DESCRIPTION OF THE DRAWINGS

(some of which have transparencies to illustrate the arrangement of components of the converter assembly)

FIG. 1: Shows a perspective view of a power board of the embodiment of a high power density converter assembly.

FIG. 2 (specifically FIGS. 2a, 2b): Shows a schematic detail view of the embodiment of a high power density converter assembly, defining the arrangement of all the components and fixtures that comprises this invention.

FIG. 3 (specifically FIGS. 3a, 3b): Shows the front and back perspective views of the power board of the embodiment of a high power density converter assembly.

FIG. 4: Shows a detail view of the power board of the embodiment.

FIG. 5: Shows a perspective view of the power board and the primary board assembly of the embodiment.

FIG. 6: Shows a detail view of the primary and power board assembly of the embodiment including the extruded profiles built in the cover of the embodiment.

FIG. 7: Shows the placement of the input bridge reflector along the back of the bridge.

FIG. 8: Shows the placement of the secondary board assembly opposite the primary board assembly.

FIG. 9: Shows a detail view of the signal board of the embodiment.

FIG. 10: Shows a detail view of the board arrangement of the embodiment.

FIG. 11 (specifically FIGS. 11a, 11b, 11c): Shows the schematic view of the arrangement of the board assembly.

FIG. 12 (specifically FIGS. 12a, 12b): Shows a potential implementation of the primary board (12b) by comparison of the previously described implementation (12a), wherein the traditional bridge rectification is replaced by a power factor correction circuit employing a magnetic element 27.

FIG. 13: Shows the overall assembly using a power Factor Correction circuit employing the magnetic element 27 in conjunction with the power train board containing the magnetic core 11.

FIG. 14: Shows a potential implementation for higher power and higher power density employing a power factor correction circuit in the primary using the magnetic core 27 and a dc-dc converter in the secondary using the magnetic core 28.

FIG. 15: Shows an planar implementation by using similar isolation methods.

### DETAILED DESCRIPTION

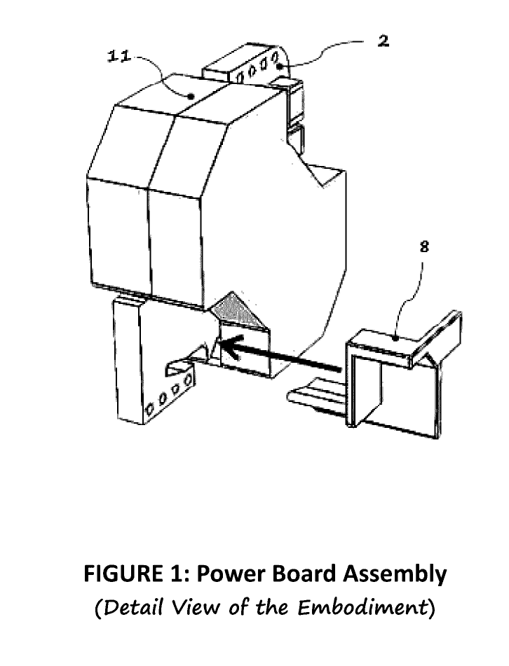

Presented in FIG. 1 is a typical arrangement of a power board assembly of the embodiment. In this figure, a typical power board (2) contains a transformer core (11) arranged in a board, which comprises of primary and secondary circuit. Moreover, the transformer can be set as part of either the primary or the secondary circuit. Such case, appropriate electrical isolation is vital between primary and secondary circuits, as well as the transformer core relative to each of the circuit and electrical components of each circuit. In this embodiment, the transformer core configured as part of the secondary circuit. The succeeding drawings will describe the importance of this particular arrangement of the transformer in relation to achieving the main goal of this invention.

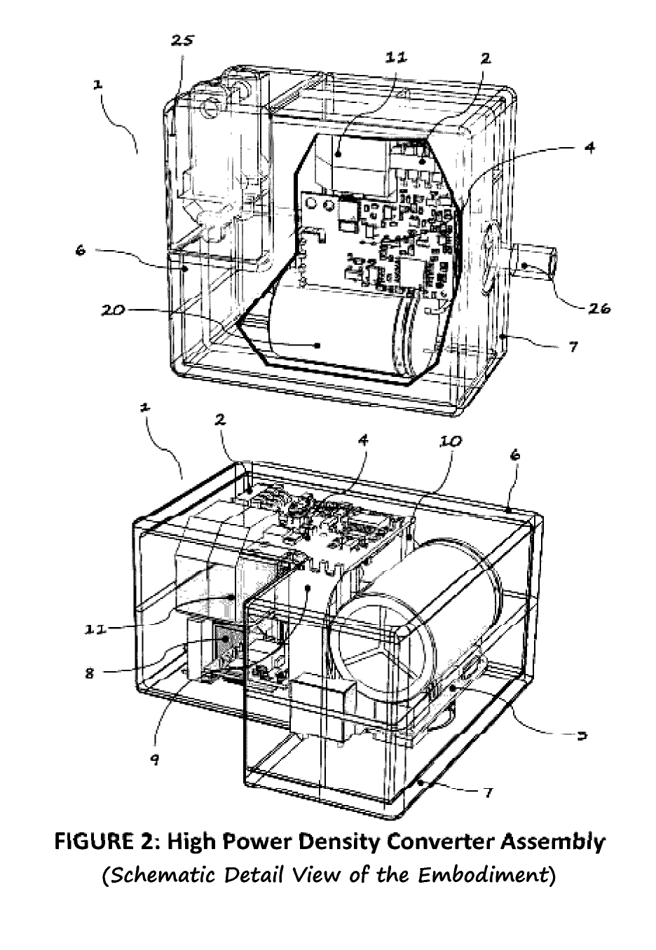

Presented in FIG. 2a, is the present invention showing the over-all physical profile of the embodiment of a high power density converter (1). It comprises of an AC plug (25) which is retractable and removable that can be switch to match most international standardized appliance connectors. The schematic detail view shows the typical components found in a typical converter (1). Such components like the bulk capacitor (20) and the transformer (11) profile, which mainly dictates the height profile of the converter (1). Moreover, the power board (2) contains the most heat dissipating devices such as transformer (11), secondary MOSFETS (12) and output capacitors. As for the primary board (3) it contains the bulk capacitor (20), primary MOSFETS, primary control, input Bridge rectifier (21), and EMI filter circuitry. As for the secondary board (4) it contains mainly the secondary controller, output switch, and output electrolytic capacitor (19). In order to distribute the thermal concerns produced mainly by the power board (2), especially the heat generated by the transformer core (11), is dispersed along the upper lateral edge of the top cover (6) and the bottom cover (7) surfaces.

As can be further explain in FIG. 2b: it shows the over-all description of how the invention is assembled together with all the components necessary to satisfy the purpose of the present invention. The schematic detail view clearly defines the uniqueness of the present invention, as you can see the strategic arrangement of all the boards such as, the primary board assembly (3), the power board assembly (2) and the secondary board assembly (4) and other high profile components such as the bulk capacitor (20). This arrangement is strategically design for a square type converter (1) with removable AC plug (25). The over-all arrangement can fit into a 52×52×28.5 (mm) profile of a power density of about 12 W/in3.

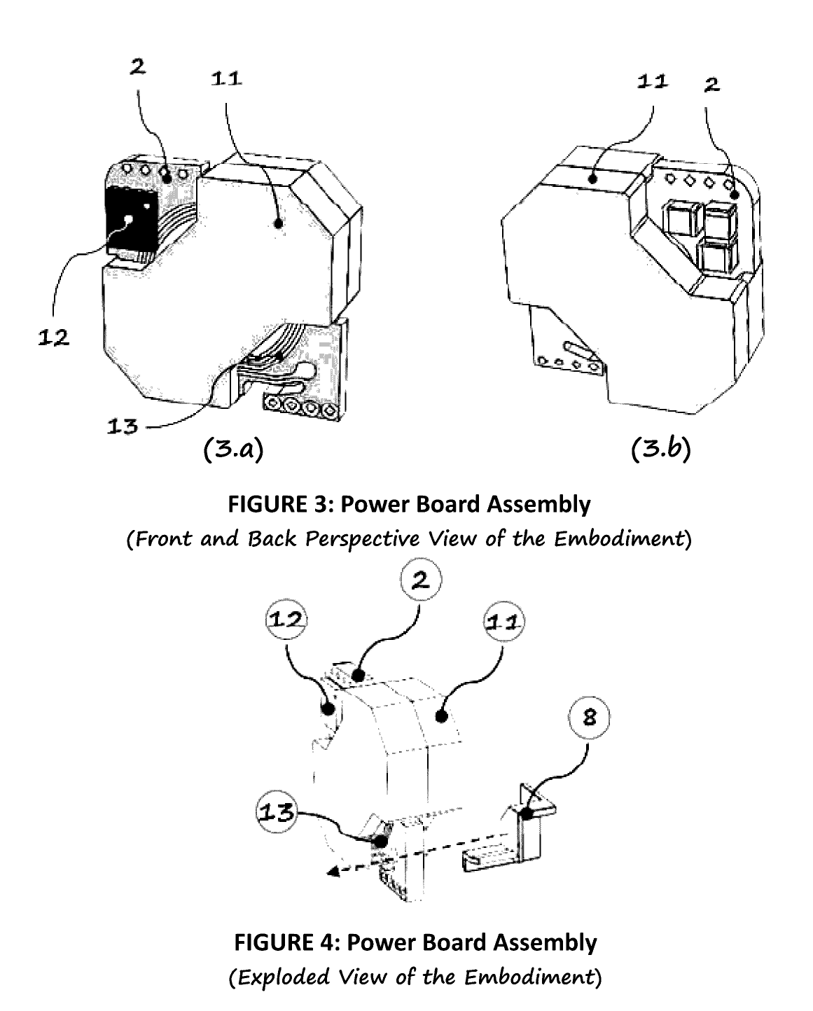

In FIG. 3 (specifically FIGS. 3a, 3b); is a perspective view power board of the embodiment, which details mainly how the power board is optimized. With the power board (2) comprising of a transformer (11), secondary MOSFETS (12), and output capacitors; this particular invention considered the transformer (11) as part of the secondary circuitry. That is, the core windings (13), secondary MOSFETS (12), and the output capacitors are strategically placed away from the primary board (3) circuitry. Taking into consideration the required safety creepage and clearance distances particularly between the transformer core (11) and the primary board (3) circuitry.

In FIG. 4; the power board (2) is mainly configured to be part of the secondary circuitry, notice that the secondary MOSFETS (12) and the output capacitors were placed on top section of the power board (2), thus the position of the primary board (3) circuitry will be opposite these components. However, part of the transformer (11) is relatively closer to the primary board (3) circuitry, in order to meet the required safety creepage and clearance distances, the power board (2), is then formed with a slot to increase the creepage and clearance using air as insulation. This separation is not enough to avoid any potential safety hazard. Accordingly, a solid insulation material added to the assembly, which reinforces the air insulation gap created by the slot. This insulation piece (8) with the sole purpose of meeting the required creepage and clearances dictated for safety requirements for this converter.

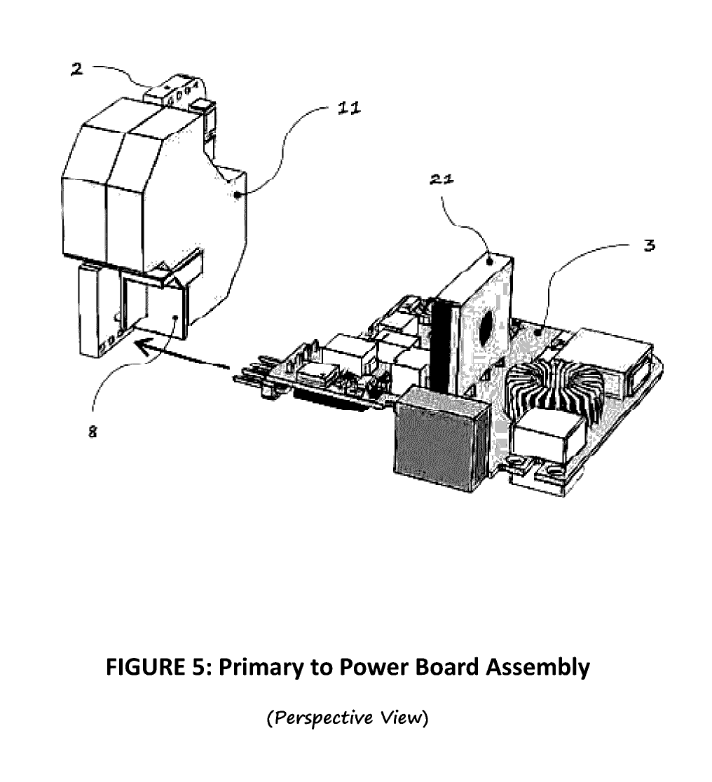

FIG. 5, shows the placement of the primary board (3) circuitry to the power board (2) assembly, via a right-angled pin connector to the bottom section of the power board assembly (2). Notice that the insulation piece is placed thru the created slot on the power board (2), the insulation piece's (8) profile is extended to create an insulated barrier between the transformer core (11) and the primary board (3) circuitry.

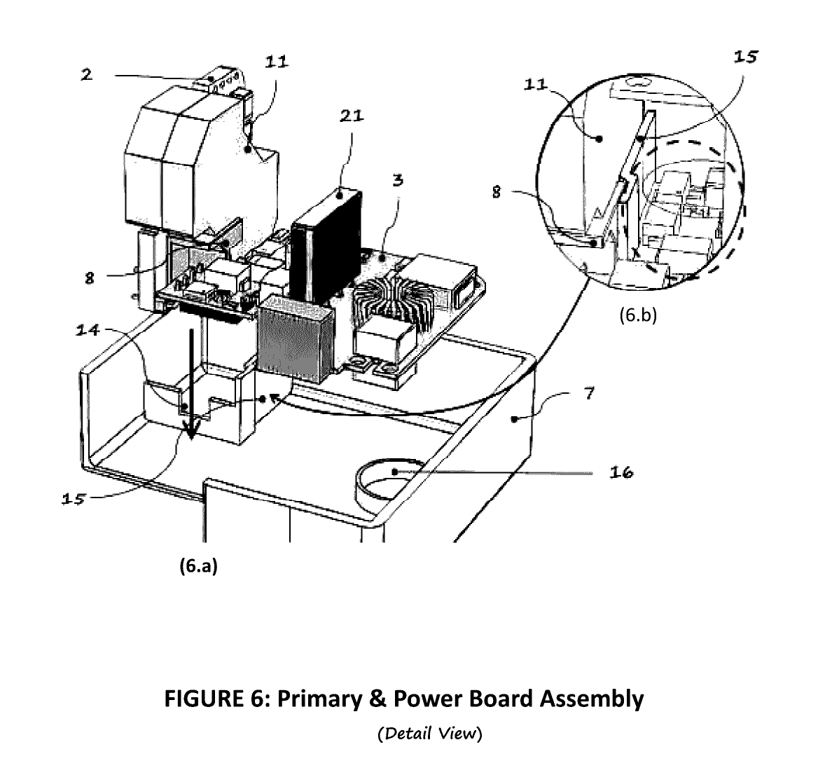

In FIG. 6.a, extruded surfaces introduced in the bottom cover (7) of the converter (1). These extruded surfaces such as the extrusion barrier 1 (14) and extrusion barrier 2 (15), further reinforces the safety creepage and clearance requirement of the converter. With the addition of these extruded profiles, this method will eventually allow you to place primary circuit components as close as possible, as shown in FIG. 6. b.

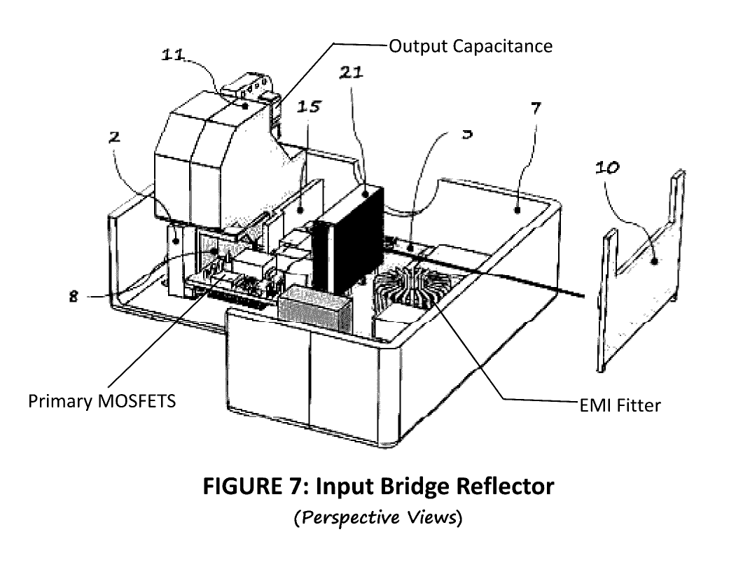

FIG. 7, shows the perspective view of the primary board (3) describing the area where the input bridge rectifier (21) is located. Affixed behind the bridge rectifier (21) is a piece of plastic called input bridge reflector (10) with an adhesive backed aluminum foil with the sole purpose of protecting parts and components from radiant heat.

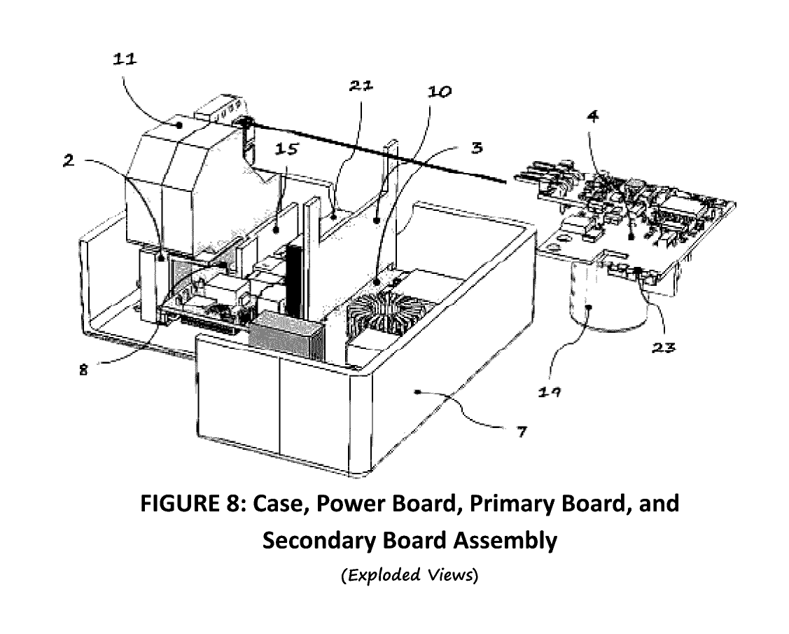

Going further, in FIG. 8, the secondary board (4) is connected through a right-angled pin connector to the top portion of the power board (2) while the primary board (3) is connected thru another right angle pin connector to the bottom portion of the power board (2). Prior to the interconnection of all three boards, an additional support called bridge reflector (10) for both boards {primary (3) and secondary (4) boards} are introduced and fastened at the back of the input bridge (21) to redirect the heat generated by the input bridge. Furthermore, the arrangement of all three boards will require an interconnection between the primary board (3) and the secondary board (4) and this is done by introducing and a signal board (9) which may contain additional circuitry or plain traces necessary to communicate with the two boards, Primary (3) and secondary (4) boards.

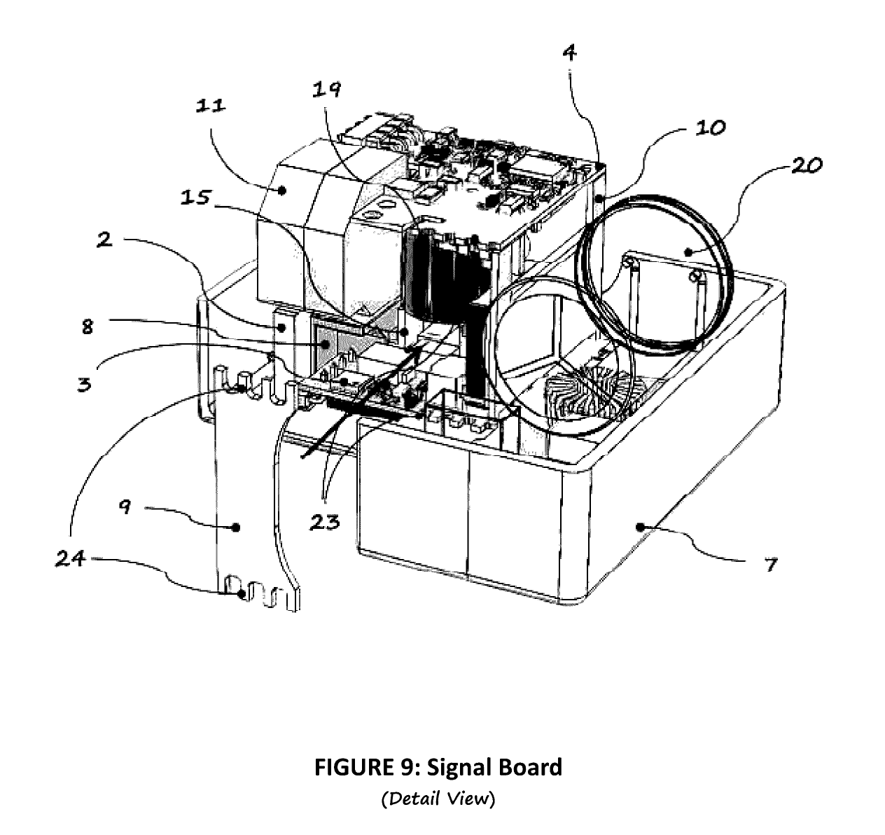

FIG. 9, shows the inter-connection of all three boards; with the use of another small board called the signal board (9). The purpose of the signal board is described in FIG. 8.

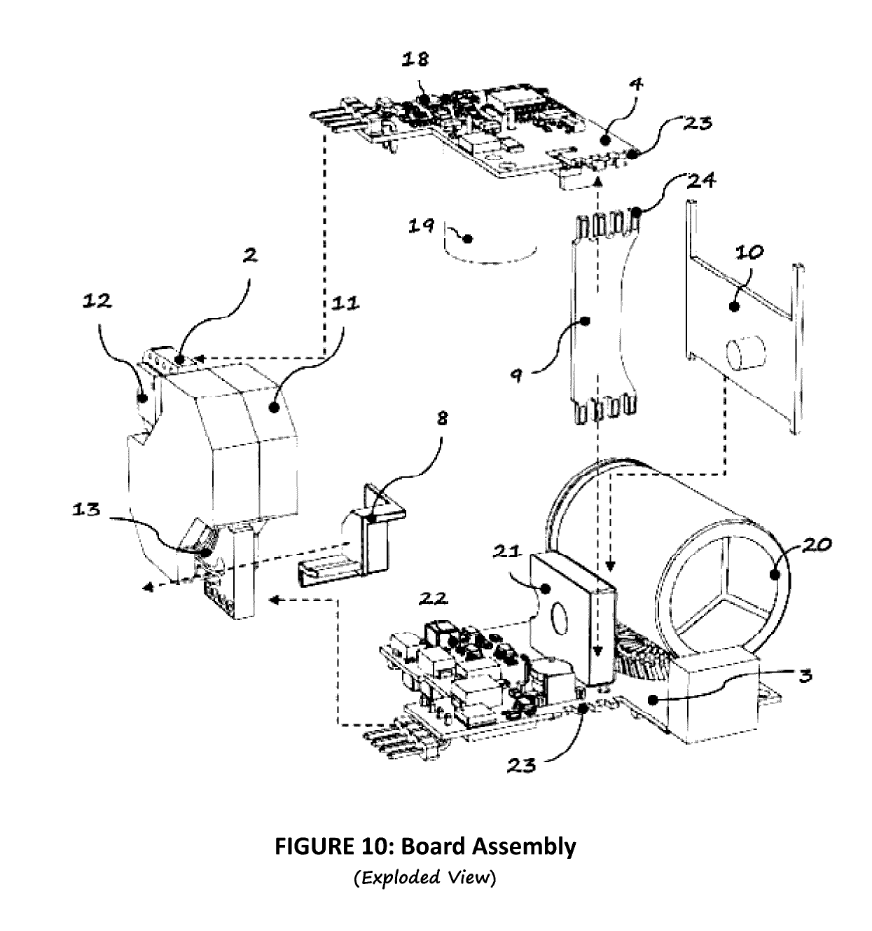

FIG. 10: shows the placement of all components and board assembly for the embodiment.

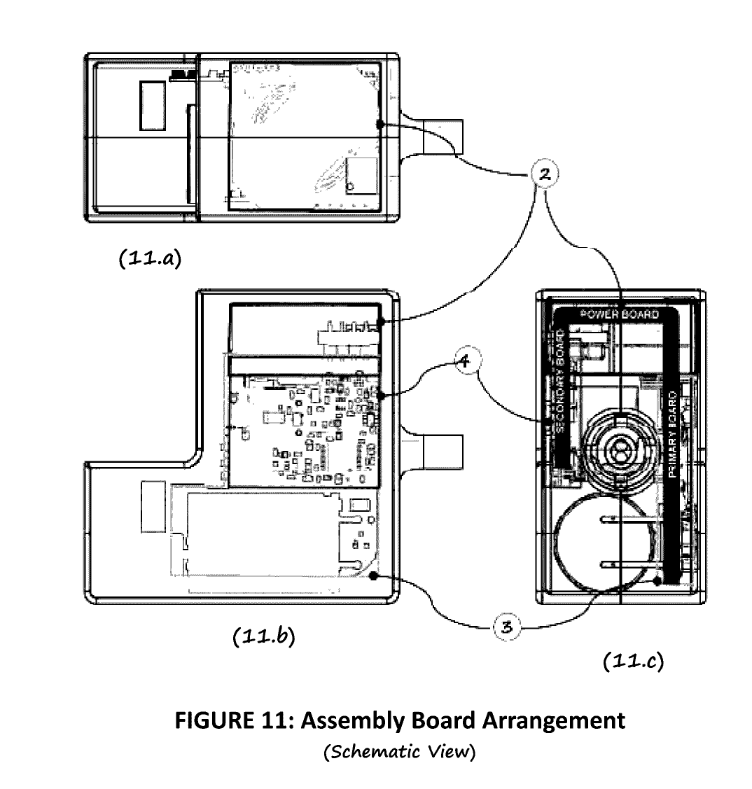

FIG. 11 (specifically FIGS. 11a, 11b, 11c): shown within is a strategic arrangement of all the assembly boards for the said embodiment. The “U” shape structure is formed by the power board assembly (2) as the base, while the boards primary (3) and secondary (4) forms the legs.

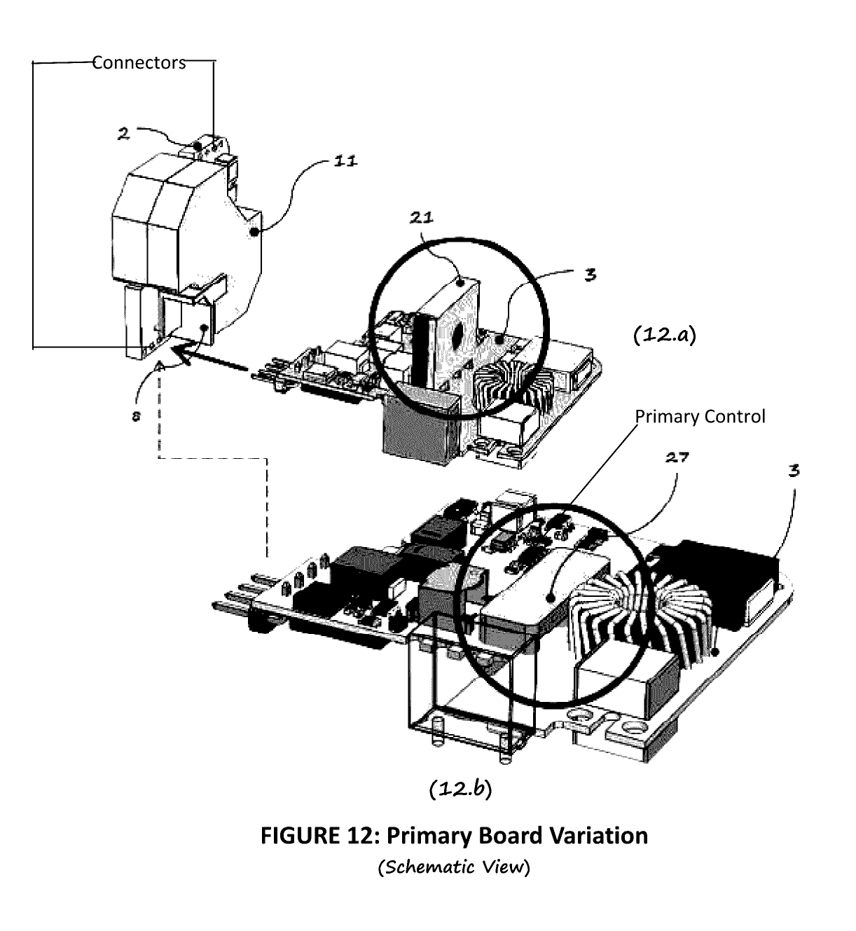

FIG. 12: For higher power application the standard bridge rectifier (21) of FIG. 12.a. is replaced by a more complex circuitry referred in the industry as power facto correction. In a power factor, correction circuit there is an inductive element, which in our case is a planar inductor using a magnetic core 27 and the winding, is embedded in the multilayer structure of the PCB. This is described in FIG. 12.b.

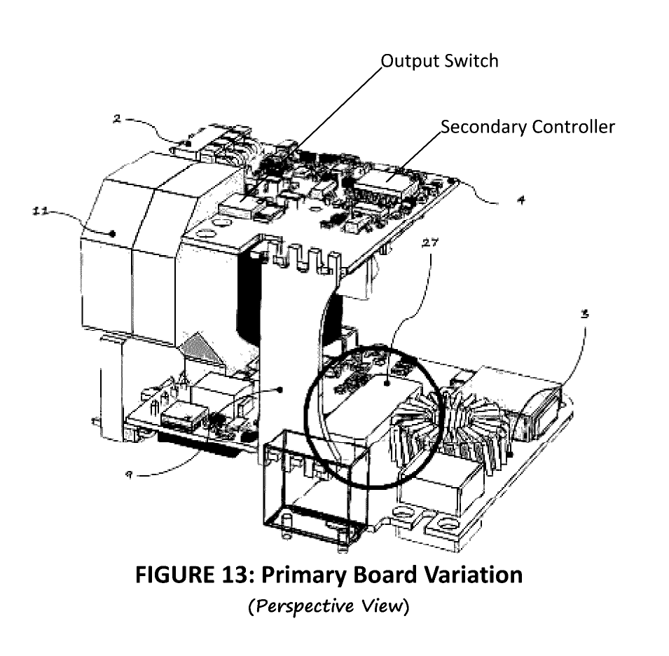

FIG. 13: This picture shows one of the embodiments of this invention, which uses a power factor correction circuit placed on the primary board. The inductive element (27) can be a discrete planar inductor or can have the winding embedded in the multilayer PCB of the primary. The power module, which converts the power after the power factor circuit to the output, remains in the same implementation as the previous embodiments of this invention.

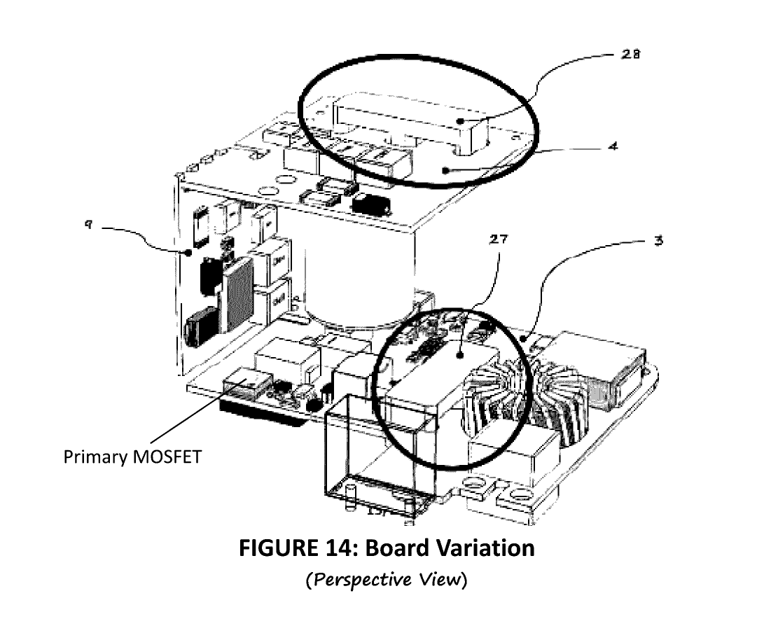

FIG. 14: This shows the packaging concept wherein the power transformer, which converts the power after the power factor correction to the output, is placed on the output board (4). In this drawing, the winding of this transformer element is embedded in the multilayer PCB of the board (4). The rectifier means of this power train are placed on the secondary board (4) very close to the winding. The primary switching elements can be placed on the transition board (9). In some very high frequency applications, the primary switchers can be placed on the secondary board (4). In such case, special spacing is required and some techniques designed to meet the safety requirements presented in the previous embodiments can be used.

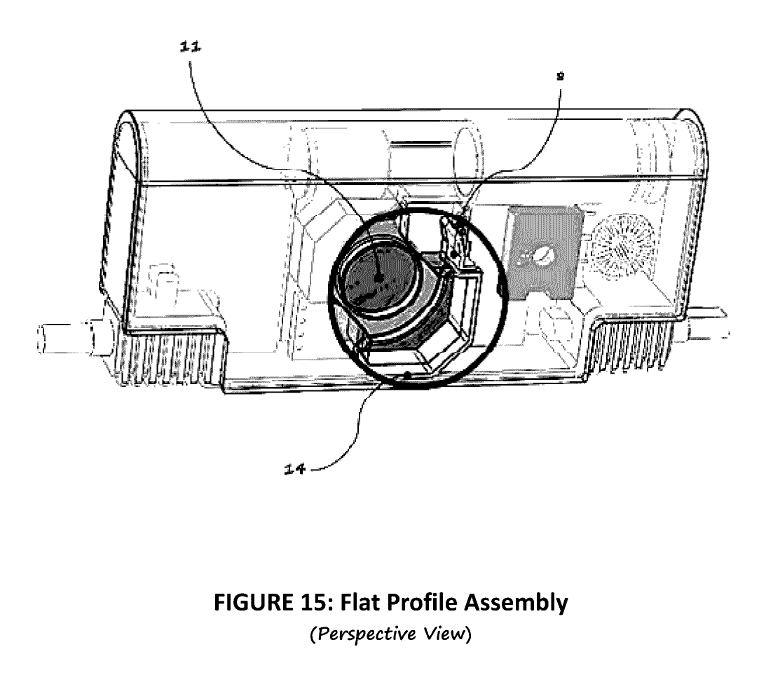

FIG. 15: This is a planar implementation of the power converter wherein the power board, which contains the synchronous rectifiers and the magnetic core, is not vertical placed on the primary board but is on the same plane with the primary and secondary board. The means to ensure compliance with safety agencies are the same as described in this patent application. The power train, which contains the power transformer and the synchronous rectifier, can be part of the same multilayer PCB or it can be implemented in a different multilayer PCB board connected to the primary and secondary board using the same connection methods presented in the main embodiments.

What is claimed is:

1. A high power density converter (1) comprising of:
an assembly of power board (2) which contains a transformer (11), Secondary MOSFETS (12), output capacitors, and connectors for electrical connection provided thereon to connect the secondary board assembly (4) and the primary board assembly (3),
wherein the power board assembly (2) is fitted with an insulation piece (8) for satisfying the clearance safety requirement for this embodiment,
wherein the primary board assembly (3) contains the bulk capacitor (20), primary MOSFETS, primary control, input bridge rectifier (21), and EMI filter circuitry,
wherein the secondary board assembly (4) contains mainly the secondary controller, output switch, and output electrolytic capacitor (19).
wherein all of the boards above when put together forms “U” shape configuration, the power board assembly (2) as the base, while the boards primary (3) and secondary (4) forms the legs.

2. The high power density converter of claim 1, wherein in a strategic arrangement of the boards according to claim 1, the power board (2) is positioned such that it is vertically placed laterally along edges of the converter (1), placing the primary board (3) laying horizontally along the bottom cover (7), while the secondary board (4) is placed opposite to the primary board laying horizontally along the top cover (6, as further illustrated in FIG. 11.

3. The power density converter according to claim 2, which has a slot to increase the creepage and clearance using air as an insulation, which separation is not enough to avoid any potential safety hazard, and wherein a solid insulation material is added to the assembly, which reinforces the air insulation gap created by the slot, which insulation piece (8) with the purpose of meeting the required creepage and clearances dictated for safety requirements for this converter (1).

4. The power density converter according to claim 1, wherein the primary board (3) on one of the components in particular, the input bridge rectifier (21) is fitted with a bridge reflector (10), this will serve as a thermal barrier to any close proximity devices, or diffusing extraneous thermal energy or dissipated heat by the input bridge (21), and wherein this bridge reflector (10) is also used as a support for both primary (3) and secondary (4) board assemblies.

5. The power density converter of claim 4, wherein a profile member is made up of thermoplastic material which when press fitted to the back of the input bridge rectifier (21) will served as a good mechanical support and thermal contact for the rectifier, and wherein this thermoplastic material coated or covered with an adhesive backed aluminum foil is to protect components and parts from radiant heat generated by the input bridge rectifier (21).

6. The power density converter of claim 4, wherein the bridge reflector (10) profile can be made up of PCB incorporating the circuitry for communication between primary (3) and secondary (4) board assemblies, and this includes copper traces to extract heat from the input bridge (21), and serve as a support for both boards above.

7. Components and board assembly for a high density converter that are put together prior to placing it into the bottom cover (7), as shown in FIG. 10 and according to the additional detailed description in FIG. 6, wherein the proximity of the primary board (3) circuitry along the body of the transformer (11) core can be as close as possible to it, and due to the extruded profile presented in the bottom cover (7), where the main purpose of this extrusions—extruded barrier 1 (14) and extruded barrier 2 (15) is to place a solid insulation in between primary and secondary circuitry components for safety requirements for the converter (1).
